(19) United States
(12) Patent Application Publication
(10) Pub. No.: US 2015/0368796 A1
(43) Pub. Date: Dec. 24, 2015

(54) APPARATUS FOR GAS INJECTION TO EPITAXIAL CHAMBER

(71) Applicant: Applied Materials, Inc., Santa Clara, CA (US)

(72) Inventors: Xuebin LI, Sunnyvale, CA (US); Kevin JOSEPH BAUTISTA, San Jose, CA (US); Avinash SHERVEGAR, Karnataka (IN); Yihwan KIM, San Jose, CA (US); Nyi O. MYO, San Jose, CA (US); Abhishek DUBE, Belmont, CA (US)

(21) Appl. No.: 14/744,296

(22) Filed: Jun. 19, 2015

Related U.S. Application Data
(60) Provisional application No. 62/014,741, filed on Jun. 20, 2014.

(51) Int. Cl. C23C 16/455; F16L 41/02

(52) U.S. Cl. CPC C23C 16/45504; C23C 16/4551; C23C 16/45563; F16L 41/02

(57) ABSTRACT

Embodiments described herein generally relate to apparatus for forming silicon epitaxial layers on semiconductor devices. Deposition gases and etching gases may be provided sequentially or simultaneously to improve epitaxial layer deposition characteristics. A gas distribution assembly may be coupled to a deposition gas source and an etching gas source. Deposition gas and etching gas may remain separated until the gases are provided to a processing volume in a processing chamber. Outlets of the gas distribution assembly may be configured to provide the deposition gas and etching gas into the processing volume with varying characteristics. In one embodiment, outlets of the gas distribution assembly which deliver etching gas to the processing volume may be angled upward relative to a surface of a substrate.

### CROSS-REFERENCE TO RELATED APPLICATIONS

This application claims benefit of U.S. Provisional Patent Application No. 62/014,741, filed Jun. 20, 2014, the entirety of which is herein incorporated by reference.

### BACKGROUND

1. Field

Embodiments of the disclosure generally relate to the field of semiconductor manufacturing equipment, and more specifically, an apparatus for gas injection to an epitaxial chamber.

2. Description of the Related Art

Size reduction of metal-oxide-semiconductor field-effect transistors (MOSFETs) has enabled the continued improvement in speed, performance, density, and cost per unit function of integrated circuits. The semiconductor industry is also in the era of transitioning from 2D transistors, which are often planar, to 3D transistors using a three-dimensional gate structure. In 3D gate structures, the channel, source and drain are raised out of the substrate and the gate is then wrapped around the channel on three sides. The goal is to constrain the current to only the raised channel, and abolish any path through which electrons may leak. One such type of 3D transistors is known as a FinFET (fin field-effect transistor), in which the channel connecting the source and drain is a thin “fin” extending from of the substrate, thereby constraining the current to the channel. As a result, electrons may be prevented from leaking.

Selective epitaxial deposition processes have been used by the industry to form epitaxial layers of silicon-containing materials, elevated source/drain structures, or source/drain extensions needed in the 3D transistors. Generally, a selective epitaxial process involves a deposition reaction and an etch reaction. Chlorine gas can be used as an etching chemical in the selective epitaxial process to achieve the process selectivity by etching away an amorphous film on dielectrics and defective epitaxial films, or during a chamber cleaning process to remove remaining deposition gases or deposited residues from chamber components. Chlorine gas generally exhibits a high degree of reactivity and can easily react with deposition process gases (which typically contain hydrogen and hydrides) even at low temperature. However, in conventional processes, the chlorine gas and the deposition process gases are normally not used together during the deposition phase to avoid affecting the film growth rate. While film growth rate or deposition efficiency of the deposition process gases can be controlled or manipulated by performing deposition reactions alternately with etching reactions, or separately introducing the etching chemical and deposition process gases into the reaction chamber with controlled time and process conditions, such approaches are complicated and time consuming, which in turn affects the throughput and overall productivity of the processing system.

Therefore, what is needed are improved gas injection apparatus capable of enabling simultaneous processes that can react etch chemicals with deposition process gases.

### SUMMARY

In one embodiment, a gas distribution manifold liner apparatus is provided which includes an inject liner. The inject liner comprises a first surface having a first plurality of outlets formed therein. One or more of the first plurality of outlets may be angled upward toward the first plurality of outlets relative to an axis. A second surface may have a second plurality of outlets formed therein. The second plurality of outlets may be disposed coplanar with the first plurality of outlets.

In another embodiment, a gas distribution manifold liner apparatus is provided which includes an inject liner. The inject liner comprises a first surface having a first plurality of outlets formed therein. One or more of the first plurality of outlets may be angled upward toward the first plurality of outlets relative to an axis. A second surface may have a second plurality of outlets formed therein. The second plurality of outlets may be disposed below the first plurality of outlets. A third surface may have the first plurality of outlet formed therein. The third surface may be coplanar with the first surface. One or more of the first plurality of outlets formed in the third surface may be angled upward relative to the axis.

In yet another embodiment, a gas distribution manifold liner apparatus is provided which includes an inject liner. The inject liner comprises a first surface having a first plurality of outlets formed therein, one or more of the first plurality of outlets may be angled upward the first plurality of outlets relative to an axis. A second surface may have a second plurality of outlets formed therein. The second plurality of outlets may be disposed below the first plurality of outlets.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic side cross-sectional view of an exemplary process chamber that may be used to practice various embodiments of this disclosure.

FIG. 1B is a schematic side cross-sectional view of the chamber of FIG. 1A rotated 90 degrees.

FIG. 2 is an isometric view of one embodiment of a gas process kit comprising one or more liners shown in FIGS. 1A and 1B.

FIG. 3 is an isometric view of the gas distribution assembly shown in FIG. 1A.

FIG. 4A is a partial isometric view of one embodiment of a process kit that may be utilized in the process chamber of FIG. 1A.

FIG. 4B is a cross-sectional view of the process kit of FIG. 4A.

FIG. 5 is a partial isometric view of another embodiment of a process kit that may be utilized in the process chamber of FIG. 1A.

FIG. 6 is a partial isometric view of another embodiment of a process kit that may be utilized in the process chamber of FIG. 1A.

To facilitate understanding, identical reference numerals have been used, where possible, to designate identical elements that are common to the figures. It is contemplated that elements disclosed in one embodiment may be beneficially utilized in other embodiments without specific recitation.

### DETAILED DESCRIPTION

Embodiments described herein generally relate to apparatus for forming silicon epitaxial layers on semiconductor devices. Deposition gases and etching gases may be provided sequentially or simultaneously to improve epitaxial layer deposition characteristics. A gas distribution assembly may be coupled to a deposition gas source and an etching gas source. Deposition gas and etching gas may remain separated until the gases are provided to a processing volume in a processing chamber. Outlets of the gas distribution assembly may be configured to provide the deposition gas and etching gas into the processing volume with varying characteristics. In one embodiment, outlets of the gas distribution assembly which deliver etching gas to the processing volume may be angled upward relative to a surface of a substrate.

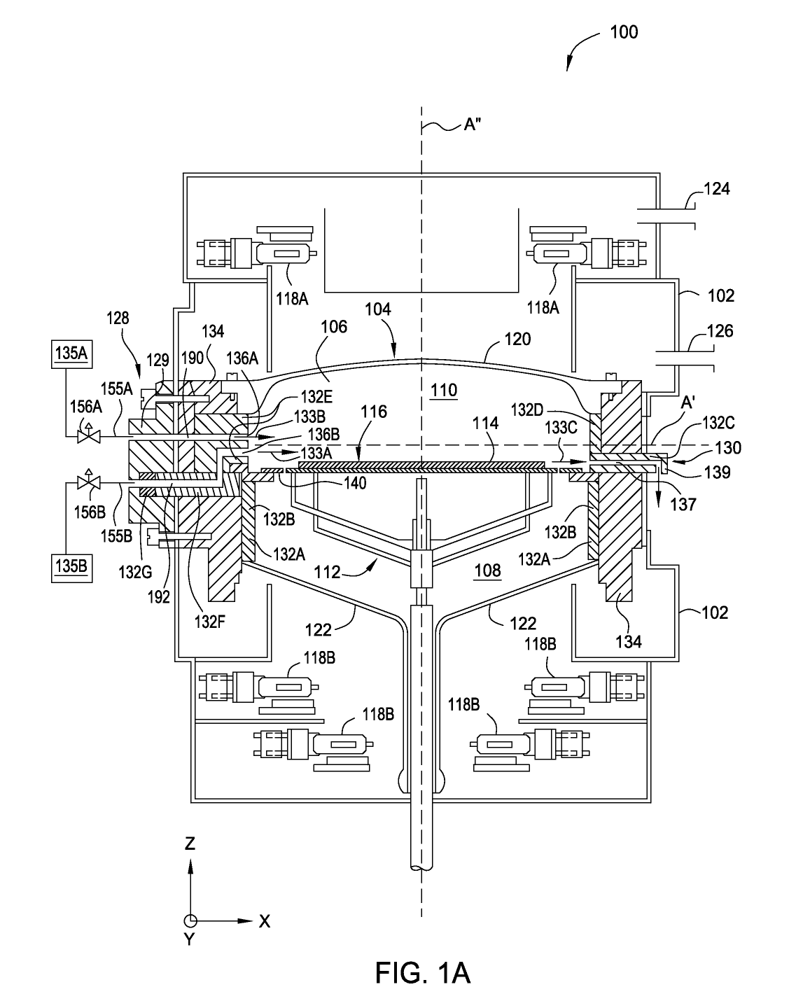

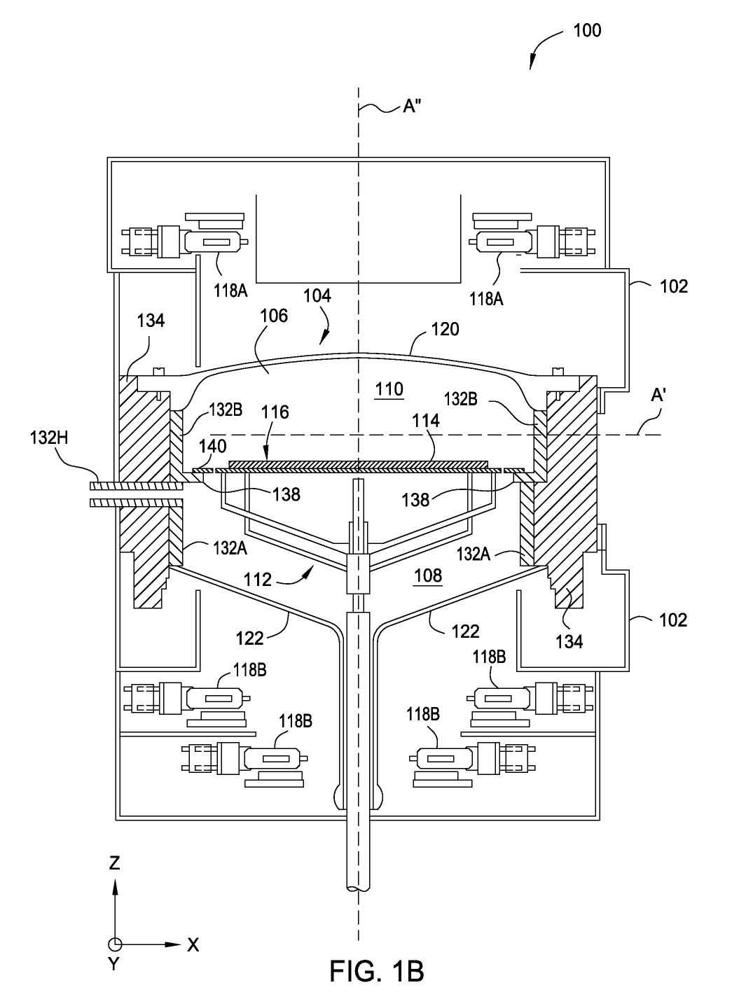

FIG. 1A is a schematic side cross-sectional view of an exemplary process chamber 100. The chamber 100 may be utilized for performing chemical vapor deposition, such as epitaxial deposition processes, although the chamber 100 may be utilized for etching or other processes. Non-limiting examples of the suitable process chamber may include the RP EPI reactor, which is commercially available from Applied Materials, Inc. of Santa Clara, Calif. While the process chamber 100 is described below may be utilized to practice various embodiments described herein, other semiconductor process chamber from different manufacturers may also be used to practice the embodiments described in this disclosure. The process chamber 100 may be added to a CENTURA® integrated processing system, also available from Applied Materials, Inc., of Santa Clara, Calif.

The chamber 100 includes a housing structure 102 made of a process resistant material, such as aluminum or stainless steel. The housing structure 102 encloses various functioning elements of the process chamber 100, such as a quartz chamber 104, which includes an upper chamber 106, and a lower chamber 108, in which a processing volume 110 is defined. A substrate support 112, which may be made of a ceramic material or a graphite material coated with a silicon material, such as silicon carbide, is adapted to receive a substrate 114 within the quartz chamber 104. Reactive species from precursor reactant materials are applied to a processing surface 116 of the substrate 114, and byproducts may be subsequently removed from the processing surface 116. Heating of the substrate 114 and/or the processing volume 110 may be provided by radiation sources, such as upper lamp modules 118A and lower lamp modules 118B. In one embodiment, the upper lamp modules 118A and lower lamp modules 118B are infrared lamps. Radiation from the lamp modules 118A and 118B travels through an upper quartz window 120 of the upper chamber 106, and through a lower quartz window 122 of the lower chamber 108. Cooling gases for the upper chamber 106, if needed, enter through an inlet 124 and exit through an outlet 126.

Reactive species are provided to the quartz chamber 104 by a gas distribution assembly 128. Processing byproducts are removed from the processing volume 110 by an exhaust assembly 130, which is typically in communication with a vacuum source (not shown). Precursor reactant materials, as well as diluent, purge and vent gases for the chamber 100, enter through the gas distribution assembly 128 and exit through the exhaust assembly 130. The chamber 100 also includes multiple liners 132A-132H (only liners 132A-132G are shown in FIG. 1A). The liners 132A-132H shield the processing volume 110 from metallic walls 134 that surround the processing volume 110. In one embodiment, the liners 132A-132H comprise a process kit that covers all metallic components that may be in communication with or otherwise exposed to the processing volume 110.

A lower liner 132A is disposed in the lower chamber 108. An upper liner 132B is disposed at least partially in the lower chamber 108 and is adjacent the lower liner 132A. An exhaust insert liner assembly 132C is disposed adjacent the upper liner 132B. In FIG. 1A, an exhaust insert liner 132D is disposed adjacent the exhaust insert liner assembly 132C and may replace a portion of the upper liner 132B to facilitate installation. An injector liner 132E is shown on the side of the processing volume 110 opposite the exhaust insert liner assembly 132C and the exhaust liner 132D. The injector liner 132E is configured as a manifold to provide one or more fluids, such as a gas or a plasma of a gas, to the processing volume 110. The one or more fluids are provided to the injector liner 132E by an inject insert liner assembly 132F. A baffle liner 132G is coupled to the inject insert liner assembly 132F. The baffle liner 132G is coupled to a first gas source 135A and an optional second gas source 135B and provides gases to the inject insert liner assembly 132F and to openings 136A and 136B formed in the injector liner 132E via a first plurality of passages 190 and a second plurality of passages 192, respectively.

The one or more gases are provided to the processing volume 110 from the first gas source 135A and the second gas source 135B. The first gas source 135A may be provided to the processing volume 110 via a pathway through an inject cap 129 and the second gas source 135B may be provided to the processing volume 110 through the baffle liner 132G. Although not shown, the first gas source 135A may be provided to the processing volume 110 through a second baffle liner or the baffle liner 132G if the first and second gases are kept separate until the gases reach the processing volume 110.

One or more first valves 156A may be formed on one or more first conduits 155A which couple the first gas source 135A to the chamber 100. Similarly, one or more second valves 156B may be formed on one or more second conduits 155B which coupled the second gas source 135B to the chamber 100. The valves 156A, 156B may be adapted to control the flow of gas from the gas sources 135A, 135B. The valves 156A, 156B may be any type of suitable gas control valve, such as a needle valve or a pneumatic valve. The valves 156A, 156B may control gas flow from the gas sources 135A, 135B in a desirable manner. In one embodiment, the one or more first valves 156A may be configured to provide a greater flow of gas from the first gas source 135A to a center region of the substrate 114. Each of the valves 156A, 156B may be controlled independently of one another and each of the valves 156A, 156B may be at least partially responsible for determining gas flow within the processing volume 110.

Gas from both the first gas source 135A and the second gas source 135B may travel through the through the one or more openings 136A and 136B formed in the injector liner 132E. In one embodiment, gas provided from the first gas source 135A may travel through the opening 136A and gas provided from the second gas source 135B may travel through the opening 136B. In another embodiment, the first gas source 135A may provide an etching gas and the second gas source 135B may provide a deposition gas.

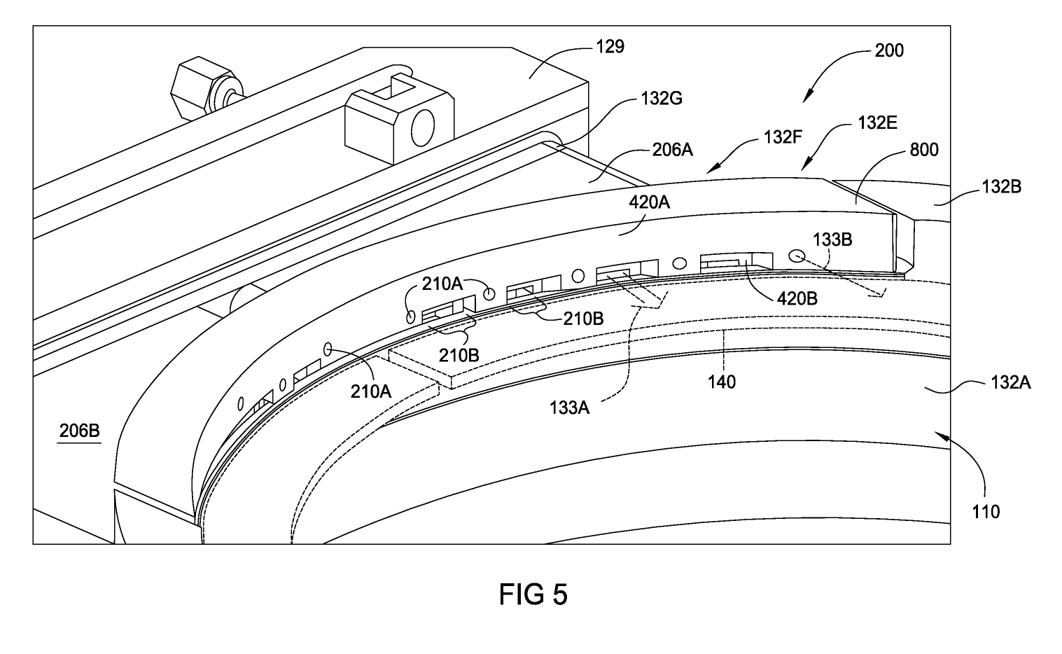

The one or more openings 136A and 136B formed in the injector liner 132E are coupled to outlets configured for a laminar flow path 133A or a jetted flow path 133B. The openings 136A and 136B may be configured to provide individual or multiple gas flows with varied parameters, such as velocity, density, or composition. In one embodiment where multiple openings 136A and 136B are adapted, the openings 136A and 136B may be distributed along a portion of the gas distribution assembly 128 (e.g., injector liner 132E) in a substantial linear arrangement to provide a gas flow that is wide enough to substantially cover the diameter of the substrate. For example, each of the openings 136A and 136B may be arranged to the extent possible in at least one linear group to provide a gas flow generally corresponding to the diameter of the substrate. Alternatively, the openings 136A and 136B may be arranged in substantially the same plane or level for flowing the gas(es) in a planar, laminar fashion, as discussed below with respect to FIG. 5. The openings 136A and 136B may be spaced evenly along the injector liner 132E or may be spaced with varying densities. For example, one or both of the openings 136A and 136B may be more heavily concentrated at a region of the injector liner 132E corresponding to a center of the substrate.

Each of the flow paths 133A, 133B are configured to flow across an axis A′ in a laminar or non-laminar flow fashion to the exhaust liner 132D. The flow paths 133A, 133B may be generally coplanar with the axis A′ or may be angled relative to the axis A′. For example, the flow paths 133A, 133B may be angled upward or downward relative to the axis A′. The axis A′ is substantially normal to a longitudinal axis A″ of the chamber 100. The flow paths 133A, 133B flow into a plenum 137 formed in the exhaust liner 132D and culminate in an exhaust flow path 133C. The plenum 137 is coupled to an exhaust or vacuum pump (not shown). In one embodiment, the plenum 137 is coupled to a manifold 139 that directs the exhaust flow path 133C in a direction that is substantially parallel to the longitudinal axis A″. At least the inject insert liner assembly 132F may be disposed through and partially supported by the inject cap 129.

FIG. 1B is a schematic side cross-sectional view of the chamber 100 of FIG. 1A rotated 90 degrees. All components that are similar to the chamber 100 described in FIG. 1A will not be described for the sake of brevity. In FIG. 1B, a slit valve liner 132H is shown disposed through the metallic walls 134 of the chamber 100. Additionally, in the rotated view shown in FIG. 1B, the upper liner 132B is shown adjacent the lower liner 132A instead of the injector liner 132E shown in FIG. 1A. In the rotated view shown in FIG. 1B, the upper liner 132B is shown adjacent the lower liner 132A on the side of the chamber 100 opposite the slit valve liner 132H, instead of the exhaust liner 132D shown in FIG. 1A. In the rotated view shown in FIG. 1B, the upper liner 132B covers the metallic walls 134 of the upper chamber 106. The upper liner 132B also includes an inwardly extending shoulder 138. The inwardly extending shoulder 138 forms a lip that supports an annular pre-heat ring 140 that confines precursor gases in the upper chamber 106.

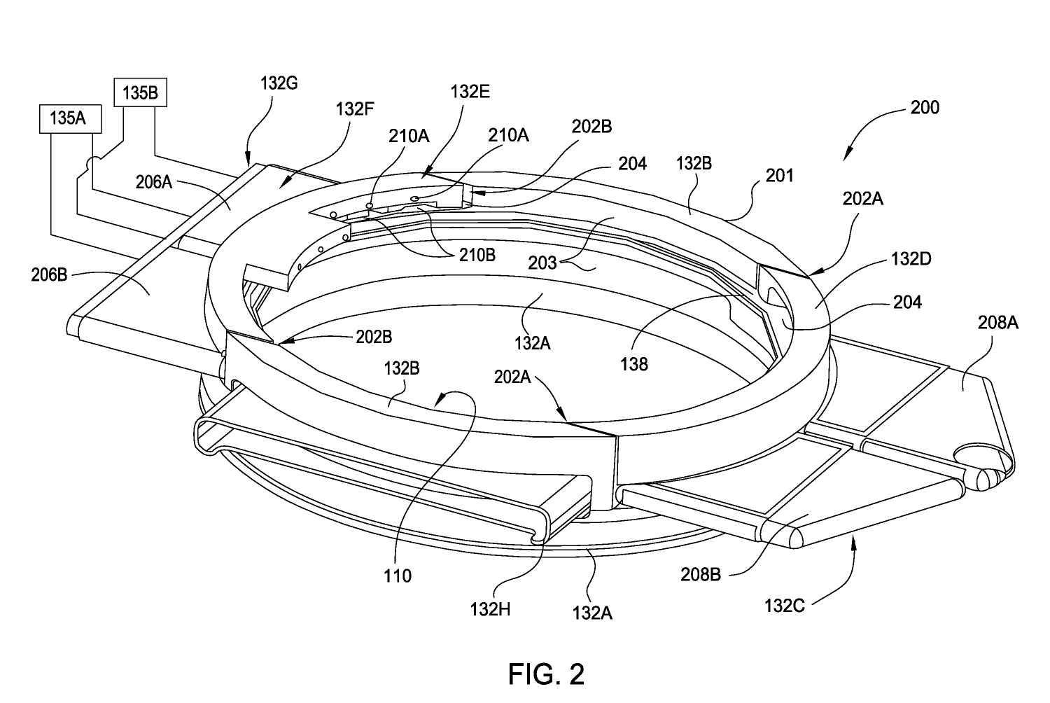

FIG. 2 is an isometric view of one embodiment of a gas process kit 200 comprising one or more liners 132A-132H as shown in FIGS. 1A and 1B. The liners 132A-132H are modular and are adapted to be replaced singularly or collectively. For example, one or more of the liners 132A-132H may be replaced with another liner that is adapted for a different process without the replacement of other liners 132A-132H. Therefore, the liners 132A-132H facilitate configuring the chamber 100 for different processes without replacement of all of the liners 132A-132H. The process kit 200 comprises a lower liner 132A and an upper liner 132B. Both of the lower liner 132A and the upper liner 132B include a generally cylindrical outer diameter 201 that is sized to be received in the chamber 100 of FIGS. 1A and 1B. Each of the liners 132A-132H are configured to be supported within the chamber by gravity and/or interlocking devices, such as protrusions and mating recesses formed in or on some of the liners 132A-132H. Interior surfaces 203 of the lower liner 132A and the upper liner 132B form a portion of the processing volume 110. The upper liner 132B includes cut-out portions 202A and 202B sized to receive the exhaust liner 132D and the injector liner 132E, which are shown in cross-section in FIG. 1A. Each of the cut-out portions 202A, 202B define recessed areas 204 of the upper liner 132B adjacent the inwardly extending shoulder 138.

In one embodiment, each of the inject insert liner assembly 132F and the exhaust insert liner assembly 132C comprise two sections. The inject insert liner assembly 132F includes a first section 206A and a second section 206B that are coupled at one side by the baffle liner 132G. Likewise, the exhaust insert liner assembly 132C includes a first section 208A and a second section 208B. Each of the sections 206A and 206B of the inject insert liner assembly 132F receive gases from the first gas source 135A and the second gas source 135B through the baffle liner 132G. Gases are flowed through the inject insert liner assembly 132F via the first plurality of passages 190 and the second plurality of passages 192 and are routed to a plurality of first outlets 210A and a plurality of second outlets 210B in the injector liner 132E. In one aspect, the inject insert liner assembly 132F and the injector liner 132E comprise a gas distribution manifold liner. Thus, the gases from the first gas source 135A and the second gas source 135B are flowed separately into the processing volume 110. In one example, gas provided from the first gas source 135A is provided to the processing volume 110 via the plurality of first outlets 210A and gas provided from the second gas source 135B is provided to the processing volume 110 via the plurality of second outlets 210B. Each of the gases may be dissociated before, during or after exiting the outlets 210A, 210B and flow across the processing volume 110 for deposition on a substrate (not shown). The dissociated precursors remaining after deposition are flowed into the exhaust insert liner assembly 132C and exhausted.

The liners 132A-132H may be installed and/accessed within the chamber 100 of FIG. 1A by removing the upper quartz window 120 from the metallic walls 134 of the chamber 100 in order to access the upper chamber 106 and the lower chamber 108. In one embodiment, at least a portion of the metallic walls 134 may be removable to facilitate replacement of the liners 132A-132H. The baffle liner 132G is coupled with the inject cap 129, which may be fastened to an exterior of the chamber 100. The lower liner 132A, which includes an inside diameter that is greater than the horizontal dimension of the substrate support 112, is installed in the lower chamber 108. The lower liner 132A may rest on the lower quartz window 122.

The exhaust insert liner assembly 132C, the inject insert liner assembly 132F, and the slit valve liner 132H may be installed after the lower liner 132A is positioned on the lower quartz window 122. The inject insert liner assembly 132F may be coupled with the baffle liner 132G to facilitate gas flow from the first gas source 135A and the second gas source 135B. The upper liner 132B may be installed after installation of the exhaust insert liner assembly 132C, the inject insert liner assembly 132F, and the slit valve liner 132H. The annular pre-heat ring 140 may be positioned on the inwardly extending shoulder 138 of the upper liner 132B. The injector liner 132E may be installed within an aperture formed in the upper liner 132B and coupled with the inject insert liner assembly 132F to facilitate gas flow from the inject insert liner assembly 132F to the injector liner 132E. The exhaust liner 132D may be installed above the exhaust insert liner assembly 132C within an aperture formed in the upper liner 132B opposite the injector liner 132E. In some embodiments, the injector liner 132E may be replaced with another injector liner configured for a different gas flow scheme. Likewise, the exhaust insert liner assembly 132C may be replaced with another exhaust insert liner assembly configured for a different exhaust flow scheme.

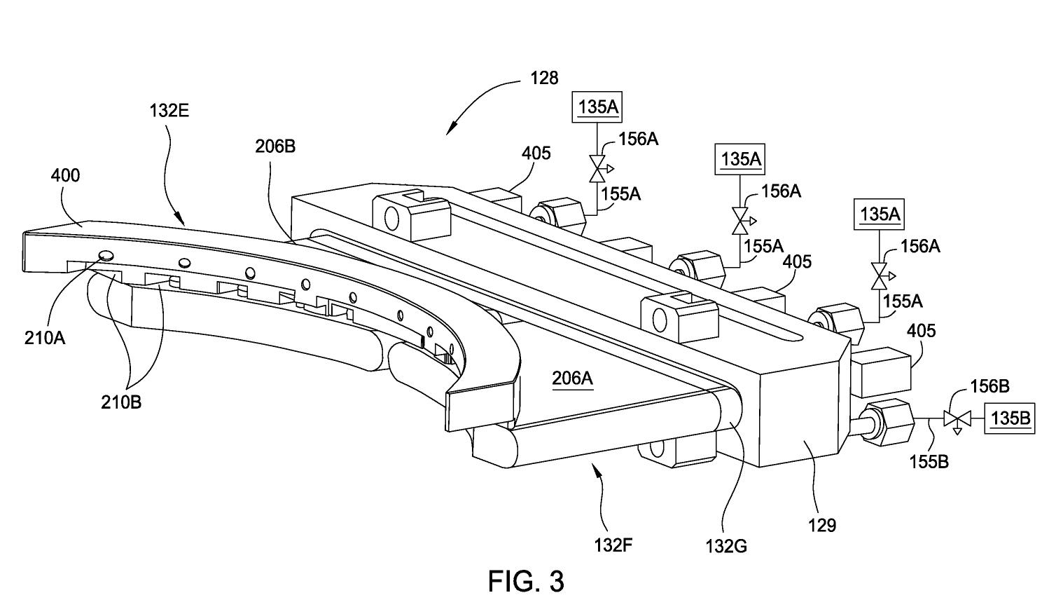

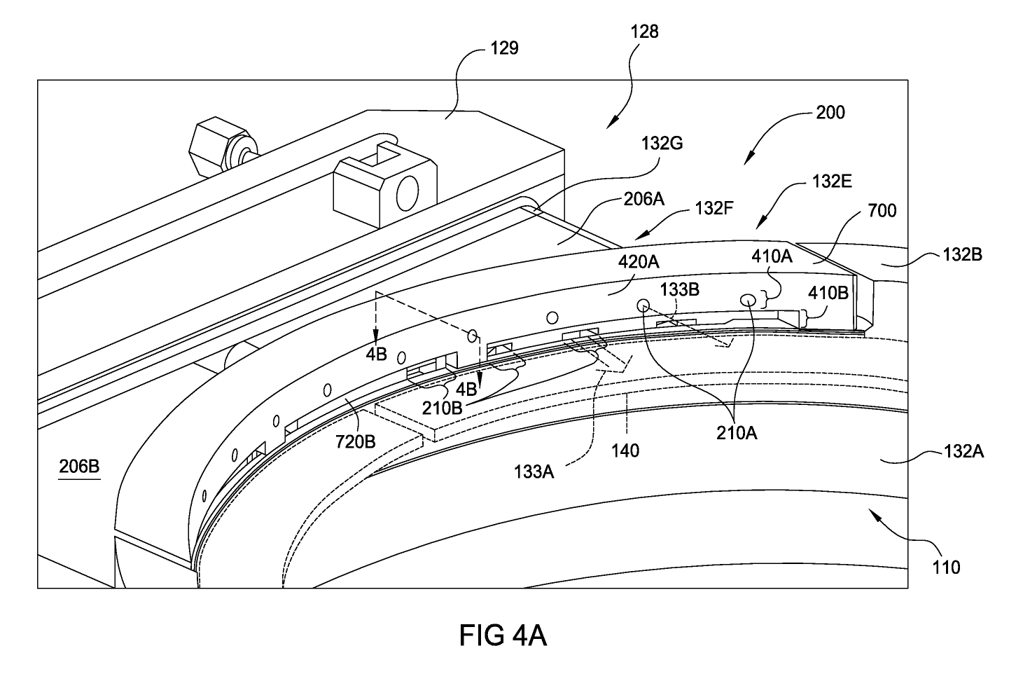

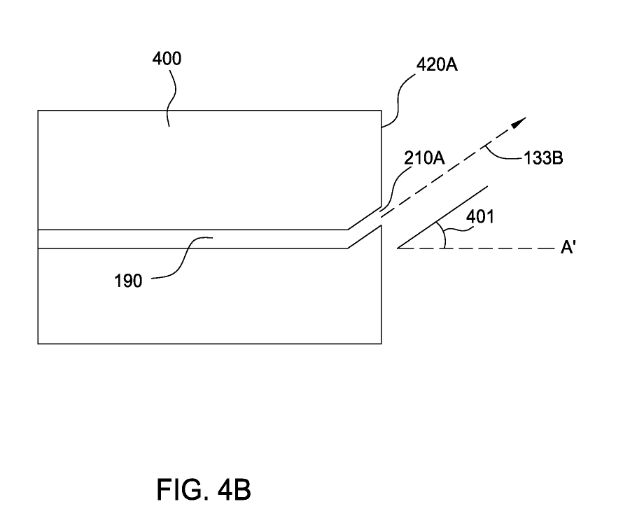

FIG. 3 is an isometric view of the gas distribution assembly 128 of FIG. 1A showing embodiments of the inject liner 132E, the inject insert liner assembly 132F, and the baffle liner 132G of FIG. 2 (collectively referring to as a gas distribution manifold liner 300). The gas distribution assembly 128 shown in FIG. 3 and various process kits 200 shown in FIGS. 4-6 may be used to practice various embodiments of the deposition process discussed in this disclosure. In one embodiment shown in FIG. 3, the injector liner 132E is coupled to the inject insert liner assembly 132F and configured to distribute gases. The gas distribution manifold liner 300 may be configured to be interchangeable with other gas distribution manifold liners.

Process gases from the first gas source 135A and the second gas source 135B are flowed through the inject cap 129. The inject cap 129 includes multiple gas passageways that are coupled to ports (not shown) formed in the baffle liner 132G. In one embodiment, lamp modules 305 may be disposed in the inject cap 129 to preheat precursor gases within the inject cap 129. The baffle liner 132G includes conduits (not shown) that flow the gases into the inject insert liner assembly 132F. The inject insert liner assembly 132F includes ports (not shown) that route gases to the first outlets 210A and the second outlets 210B of the gas distribution manifold liner 300. In one embodiment, the gases from the first gas source 135A and the second gas source 135B remain separated until the gases exit the first outlets 210A and the second outlets 2108, respectively.

In one aspect, the gases are preheated within the inject cap 129 and one or more of the baffle liner 132G, the inject insert liner assembly 132F, and the gas distribution manifold liner 300. The preheating of the gases may be provided by one or combination of the lamp modules 305 on the inject cap 129, the upper lamp modules 118A, and the lower lamp modules 118B (both shown in FIG. 1A). In one aspect, the gases are heated by energy from the lamp modules 305 on the inject cap 129, the upper lamp modules 118A, and/or the lower lamp modules 118B such that the gases are dissociated or ionized prior to or exiting the first outlets 210A and the second outlets 210B. Depending on the dissociation temperature of process gases utilized in the first gas source 135A and the second gas source 135B, only one of the gases may be ionized when exiting the gas distribution manifold liner 300 while the other gas heated but remains in gaseous form when exiting the gas distribution manifold liner 300.

FIG. 4A is a partial isometric view of one embodiment of a process kit 200 that may be utilized in the chamber 100 of FIG. 1A. The process kit 200 may include one embodiment of an injector liner 132E, shown as a gas distribution manifold liner 400, that may be coupled to the inject insert liner assembly 132F. A baffle liner 132G is shown between the inject cap 129 and the sections 206A and 206B of the inject insert liner assembly 132F. The gas distribution manifold liner 400 may include a dual zone inject capability wherein each zone provides different flow properties, such as a velocity. The dual zone injection comprises a first injection zone 410A and a second injection zone 410B disposed in different planes that are spaced vertically. In one embodiment, each of the injection zones 410A and 410B are be spaced-apart to form an upper zone and a lower zone. Alternatively, the first outlets 210A and the second outlets may be disposed in substantially in the same plane or level, as shown in FIG. 5. The process kit 200 shown in FIG. 5 is similar to the process kit 200 shown in FIG. 4A with the exception of a different embodiment of an injector liner 132E, shown as a gas distribution manifold liner 500.

Referring back to FIG. 4A, the first injection zone 410A includes a plurality of first outlets 210A and the second injection zone 410B includes a plurality of second outlets 210B. In one embodiment, each of the first outlets 210A are disposed in a first surface 420A of the gas distribution manifold liner 400 while each of the second outlets 210B are disposed in a second surface 420B of the gas distribution manifold liner 400 that is recessed from the first surface 420A. For example, the first surface 420A may be formed on a radius that is less than the radius utilized to form the second surface 420B.

FIG. 4B is a cross-sectional view of the gas distribution manifold liner 400 taken along section line 4B-4B. Each of the first plurality of passages 190 may be angled upward relative to the axis A′. For example, at least a portion of each of the first plurality of passages 190 may be disposed at an upward angle 401 relative to axis A′. In one embodiment, the angle 401 may be between about 1° and about 45°, such as between about 5° and about 15°. It is contemplated that gas provided from the first gas source 135A to the processing volume 110 via the first plurality of outlets 210A may be directed upward relative to the axis A′ such that the gas has a better probability of reaching the center of the substrate 114. The flow path 133B illustrates the flow of gas exiting first plurality of outlets 210A. By angling the gas provided via the first plurality of outlets 210A away from the flow path of the gas provided via the second plurality of outlets 210B, it is believed that less interaction between the gases may be achieved. As such, the gas provided through the first plurality of outlets 210A may have a greater degree of reactivity when the gas reaches the substrate 114.

Referring back to FIG. 4A, the injection zones 410A and 410B may be adapted to provide different fluid flow paths where flow metrics, such as fluid velocity, may be different. For example, the first outlets 210A of the first injection zone 410A may provide fluids at a higher velocity to form a jetted flow path 133B while the second outlets 210B of the second injection zone 410B may provide a laminar flow path 133A. The laminar flow paths 133A and jetted flow paths 133B may be provided by one or a combination of gas pressure, size of the outlets 210A, 210B, sizes (e.g., cross-sectional dimensions and/or lengths) of conduits (not shown) disposed between the outlets 210A, 210B and the gas sources 135A, 135B, and the angle and/or number of bends in the conduits disposed between the outlets 210A, 210B and the gas sources 135A, 135B. Velocity of fluids may also be provided by adiabatic expansion of the precursor gases as the fluids enter the processing volume 110.

In one aspect, the dual zone injection provided by the first injection zone 410A and the second injection zone 410B facilitates a varied level of injection for different gases. In one embodiment, the first injection zone 410A and the second injection zone 410B is spaced-apart in different planes to provide a precursor to the processing volume 110 (shown in FIG. 1A) at different vertical distances above the processing surface 116 of the substrate 114 (both shown in FIG. 1A). This vertical spacing may provide enhanced deposition parameters by accounting for adiabatic expansion of certain gases that may be utilized. In some embodiments (not shown), the first outlets 210A of the first injection zone 410A may be oriented such that one or more of the first plurality of passages 190 coupled to the first outlets 210A are at the angle 401 with respect to the processing surface of the substrate 114, or the axis A′. A described with regard to FIG. 4B, the angle 401 may be oriented upward from the axis A′.

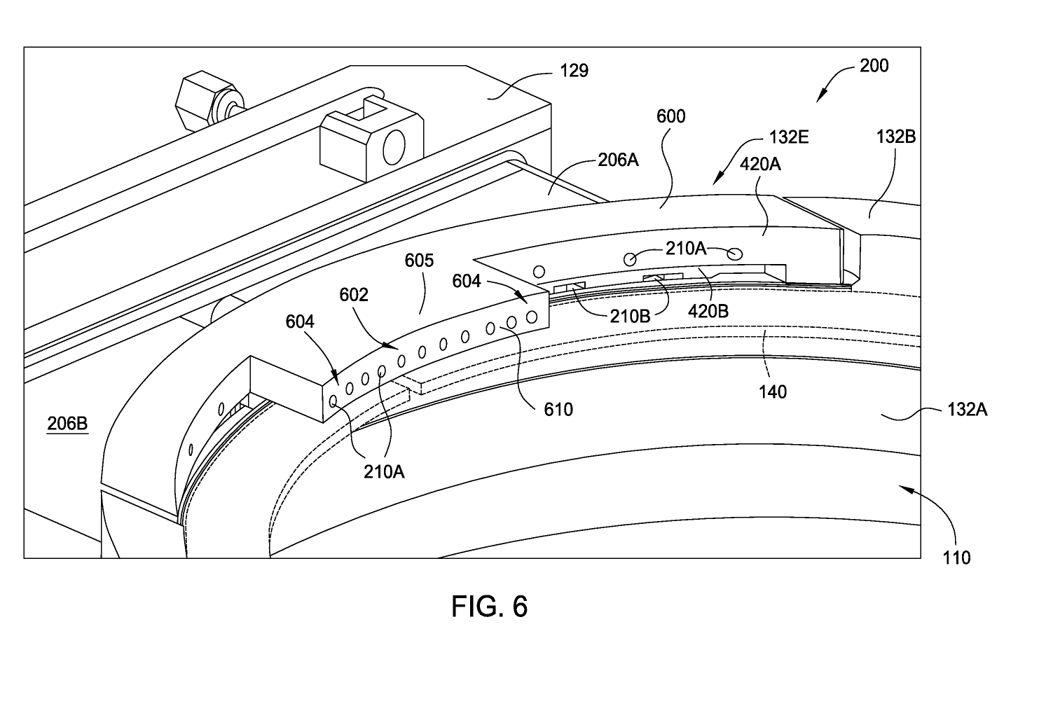

FIG. 6 is a partial isometric view of another embodiment of a process kit 200 that may be utilized in the chamber 100 of FIG. 1A. The process kit 200 is similar to the process kit 200 shown in FIGS. 4A or 5 with the exception of a different embodiment of an injector liner 132E, shown as a gas distribution manifold liner 600. In this embodiment, the gas distribution manifold liner 600 includes an extended member 605 extending inwardly from the first surface 420A. The extended member 605 includes a third surface 610 that extends further into the processing volume 110 than each of the first surface 620A and second surface 620B of the gas distribution manifold liner 600. The extended member 605 may extend a distance radially inward from the first surface 420A toward the substrate 114. In one embodiment, the extended member 605 may extend from the first surface 420A between about 15 mm and about 45 mm. The extended member 605 may extend radially inward such that the third surface 610 is disposed above an edge of the substrate 114. The extended member 605 may even extend beyond the edge of the substrate 114 toward the center of the substrate 114.

The extended member 605 includes a portion of the first outlets 210A while the remainder of the first outlets 210A are disposed in the first surface 420A of the gas distribution manifold liner 600. In one embodiment, a greater density of first outlets 210A may be formed in the extended member 605 as opposed to the first plurality of outlets 210A disposed on the first surface 420A. For example, the density of the first outlets 210A disposed on the third surface 610 may be between about 1.1 and about 5 times greater than the density of the first outlets 210A disposed on the first surface 420A. As such, spacing between the first outlets 210A on the third surface 610 may be less than the spacing between the first outlets 210A on the first surface 420A.

In one embodiment, the first outlets 210A on the third surface 610 may be spaced apart evenly. In another embodiment, the first outlets 210A on the third surface 610 may be variably spaced. For example, spacing of the first outlets 210A near a center region 602 of the extended member 605 may be less than the spacing of the first outlets 210A near edge regions 604 of the extended member 605. Accordingly, a greater density of first outlets 210A may be formed at the center region 602 of the extended member 605. It is contemplated that increasing the density of the first outlets 210A on the third surface 610 of the extended member 605 may provide for improved gas delivery to a center region of the substrate 114. It is contemplated that the feature of first outlet density may be incorporated on any of the gas distribution manifold liners 300, 400, 500 depicted in FIG. 3, FIG. 4, and FIG. 5, respectively.

One or a combination of the flow paths provided by the first outlets 210A and the second outlets 210B enables deposition uniformity and uniform growth across the substrate (not shown). In one embodiment, the first outlets 210A of the extended member 605 are utilized to inject precursor gases that tend to dissociate faster than precursors provided by the second outlets 210B. For example, Cl₂ may be provided by the first outlets 210A given the high dissociation characteristics of chlorine gas. This provides an extended flow path to inject the faster dissociating precursor a further distance and/or closer to the center of the substrate 114. Thus, the combination of precursors from both of the first outlets 210A and the second outlets 210B provides uniform distribution and growth across the substrate 114.

While the foregoing is directed to embodiments of the present disclosure, other and further embodiments of the disclosure may be devised without departing from the basic scope thereof, and the scope thereof is determined by the claims that follow.

We claim:

1. An inject liner apparatus, comprising:
a first surface having a first plurality of outlets formed therein for a first plurality of passages formed in the inject liner, wherein one or more of the first plurality of passages are angled upward toward the first plurality of outlets relative to a first axis; and
a second surface having a second plurality of outlets formed therein for a second plurality of passages formed in the inject liner, wherein the second plurality of outlets are coplanar with the first plurality of outlets.

2. The apparatus of claim 1, wherein the first surface is located at a first radius and the second surface is located at a second radius from a second axis different than the first radius.

3. The apparatus of claim 2, wherein the first radius is less than the second radius.

4. The apparatus of claim 2, wherein the first axis corresponds to a surface of a substrate support and the second axis corresponds to a rotational axis of the substrate support.

5. The apparatus of claim 4, wherein the one or more of the first plurality of outlets are angled upward between about 1° and about 45°.

6. The apparatus of claim 1, wherein a density of the first plurality of outlets is greater at a center region of the first surface than at an edge region of the first surface.

7. The apparatus of claim 1, wherein the first plurality of outlets are fluidly coupled to a first gas source separately from the second plurality of outlets which are fluidly coupled to a second gas source.

8. The apparatus of claim 7, wherein the first plurality of outlets are coupled to a Cl₂ source.

9. An inject liner apparatus, comprising:
a first surface having a first plurality of outlets formed therein for a first plurality of passages formed in the inject liner, wherein one or more of the first plurality of passages are angled upward toward the first plurality of outlets relative to a first axis;
a second surface having a second plurality of outlets formed therein for a second plurality of passages formed in the inject liner, wherein the second plurality of outlets are disposed below the first plurality of outlets; and
a third surface having the first plurality of outlets formed therein for the first plurality of passages formed in the inject liner, the third surface being coplanar with the first surface, and wherein one or more of the first plurality of passages formed adjacent the third surface are angled upward toward the first plurality of outlets relative to the first axis.

10. The apparatus of claim 9, wherein the first surface is located a first radius from a second axis, the second surface is located a second radius from the second axis different than the first radius, and the third surface is located at a third radius from the second axis different than the first radius and the second radius.

11. The apparatus of claim 10, wherein the first radius is less than the second radius and the third radius is less than the first radius.

12. The apparatus of claim 9, wherein the first axis corresponds to a surface of a substrate support and the second axis corresponds to a rotation axis of the substrate support.

13. The apparatus of claim 12, wherein the one or more of the first plurality of passages are angled upward between about 1° and about 45°.

14. The apparatus of claim 9, wherein a density of the first plurality of outlets is greater at a center region of the third surface than at an edge region of the third surface.

15. The apparatus of claim 9, wherein the first plurality of outlets are fluidly coupled to a first gas source separately from the second plurality of outlets which are fluidly coupled to a second gas source.

16. An inject liner apparatus, comprising:
a first surface having a first plurality of outlets formed therein for a first plurality of passages formed in the inject liner, wherein one or more of the first plurality of passages are angled upward toward the first plurality of outlets relative to an axis; and
a second surface having a second plurality of outlets formed therein for a second plurality of passages formed in the inject liner, wherein the second plurality of outlets are disposed below the first plurality of outlets.

17. The apparatus of claim 16, wherein the axis corresponds to a surface of a substrate support.

18. The apparatus of claim 17, wherein the one or more of the first plurality of passages are angled upward between about 1° and about 45°.

19. The apparatus of claim 16, wherein a density of the first plurality of outlets is greater at a center region of the first surface than at an edge region of the first surface.

20. The apparatus of claim 16, wherein the first plurality of outlets are fluidly coupled to a first gas source via the first plurality of passages separate from the second plurality of outlets which are fluidly coupled to a second gas source via the second plurality of passages.
